(19) United States
(12) Patent Application Publication
(10) Pub. No.: US 2015/0351275 A1
(43) Pub. Date: Dec. 3, 2015

(54) Thin-Film Radio Frequency Power Terminator

(71) Applicant: Johanson Manufacturing Corporation, Boonton, NJ (US)

(72) Inventors: Mark Imbimbo, Butler, NJ (US); Hatem Aead, West Paterson, NJ (US)

(73) Assignee: Johanson Manufacturing Corporation, Boonton, NJ (US)

(21) Appl. No.: 14/292,242

(22) Filed: May 30, 2014

(51) Int. Cl. H05K 7/06; H05K 3/10

(52) U.S. Cl. CPC H05K 7/06; H05K 3/10

(57) ABSTRACT

A thin-film, radio frequency terminator is provided that includes a mounting flange and a thin-film termination chip mounted on a surface of the mounting flange. The mounting flange grounds the termination chip. The termination chip includes a substrate, a terminal, a metallization layer including a resistor pad electrically connecting the terminal to the mounting flange, and a cover. The terminator has a low physical profile but provides high power handling capability.

### BACKGROUND OF THE INVENTION

1. Field of the Invention

The present invention relates to radio frequency (RF) power electronics. More specifically, the present invention relates to a thin-film RF power terminator.

2. Related Art

Terminators provide electrical resistance to present an electrical load to an RF transmitter and an associated transmission line. Additionally, terminators prevent a signal from being reflected back from the end of the transmission line and causing interference. Often, terminators are used in wireless communications networks. For example, a terminator can be incorporated in a transmitter circuit of a wireless node (e.g., a base station, a relay station, a mobile device, etc.). Unfortunately, terminators often have bulky configurations that create design challenges, particularly when the terminators must handle significant (e.g., 1000 Watts or greater) power loads. As such, there is a need to provide high-power RF terminators that have a lower profile while providing sufficient power handling capability.

### SUMMARY OF THE INVENTION

The present invention relates to a high-power, thin-film radio frequency power terminator. The terminator includes a mounting flange and a thin-film termination chip mounted on a surface of the mounting flange. The mounting flange provides a ground terminal for the termination chip. The termination chip is manufactured using thin-film manufacturing techniques, and includes a substrate, a terminal, a metallization layer including a resistor pad electrically connecting the terminal to the mounting flange, and a cover. Advantageously, the terminator has a low physical profile but provides high power handling capability.

The present disclosure also relates to a method for manufacturing a thin-film radio frequency power terminator. The method includes the steps of forming a thin-film termination chip, and mounting the termination chip to a mounting flange so that the mounting flange grounds the termination chip. The step of forming the thin-film termination chip could include forming a substrate, forming a metallization layer including a resistor pad on the substrate, soldering a terminal to the metallization layer, and mounting a cover on the substrate and the metallization layer.

### BRIEF DESCRIPTION OF THE DRAWINGS

The foregoing features of the invention will be apparent from the following Detailed Description of the Invention, taken in connection with the accompanying drawings, in which:

FIG. 1 is a top view showing the terminator of the present invention;

FIG. 2 is a side view of the terminator shown in FIG. 1;

FIG. 3 is a perspective view of the termination chip shown in FIG. 1;

FIG. 4 is a sectional view of the termination chip shown in FIG. 1, taken along line 4-4 of FIG. 3;

FIGS. 5-6 are graphs showing performance characteristics of the terminator shown in FIG. 1; and

FIG. 7 is a flowchart showing method steps for manufacturing the terminator shown in FIG. 1.

### DETAILED DESCRIPTION OF THE INVENTION

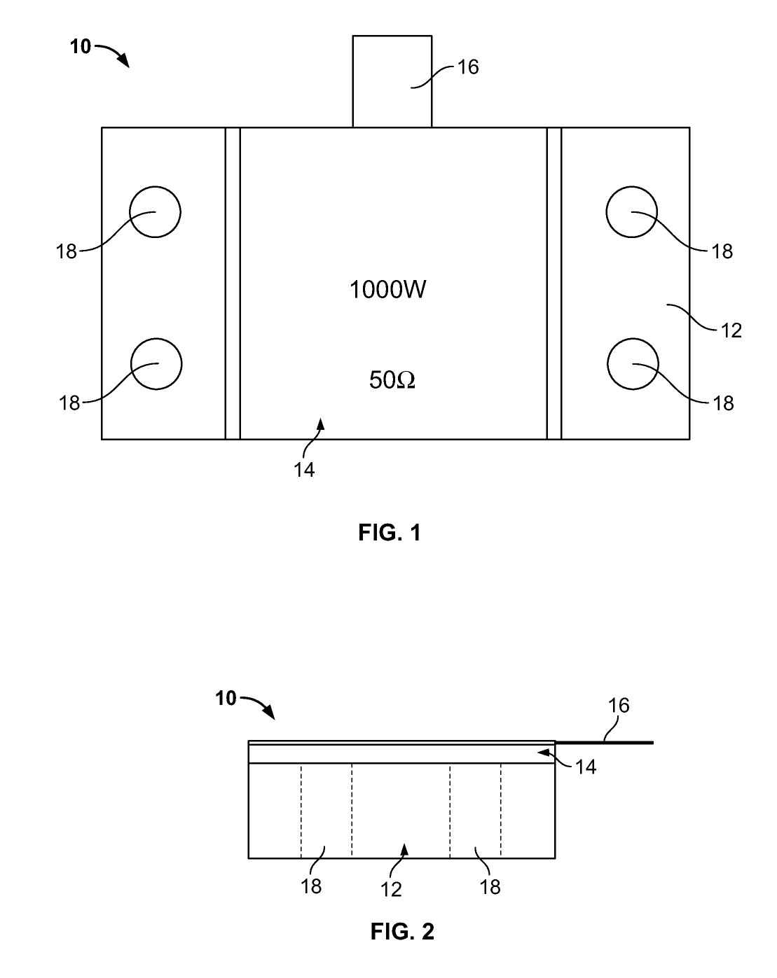

The present invention relates to a thin-film, high-power radio frequency terminator, as discussed in detail below in connection with FIGS. 1-7.

FIG. 1 is a top view showing the terminator of the present invention, indicated generally at 10. The terminator 10 includes a termination chip 14 that is mounted on a mounting flange 12. As seen in FIG. 1, both the termination chip 14 and the mounting flange 12 have rectangular shapes, but of course, other shapes and/or geometries can be provided. A terminal 16 protrudes from the termination chip 14 and is electrically connectable to an RF circuit. The profile of the mounting flange 12 is greater than that of the termination chip 14 (e.g., mounting flange 12 is wider than the termination chip 14) to accommodate mounting holes 18 on opposite sides of the termination chip 14. As indicated in FIG. 1, the terminator 10 could have a resistance of 50 ohms, but of course, other resistances and/or impedances are possible.

FIG. 2 is a side view of the terminator 10, showing the termination chip 14 and the mounting flange 12. The termination chip 14 can have a substantially hexahedral shape, and the terminal 16 protrudes from one of the surfaces while the other five surfaces of the termination chip 14 can be substantially smooth and flush. This flush design is achieved by a metallization stackup of the termination chip 14, which will be described in further detail below. As shown, a bottom surface of the termination chip 14 includes a bottom metallized layer 25 which is mounted on a top surface of the mounting flange 12. For example, the termination chip 14 can be high temperature soldered to the mounting flange 12. The mounting holes 18 extend through the mounting flange 12, from the top surface to a bottom surface of the mounting flange 12. Thus, the mounting holes 18 can receive attachment means (e.g., screws, bolts, etc.) for mounting the terminator 10 to a mounting surface (e.g., to a circuit board). The mounting flange 12 is made of a material with strong thermal conductive properties, such as copper, and the mounting flange 12 can be nickel plated. As such, while the mounting flange 12 serves to ground the RF signal receivable by the termination chip 14, the mounting flange 12 also acts as a heat dissipating element, transferring heat from the termination chip 14 to the mounting surface.

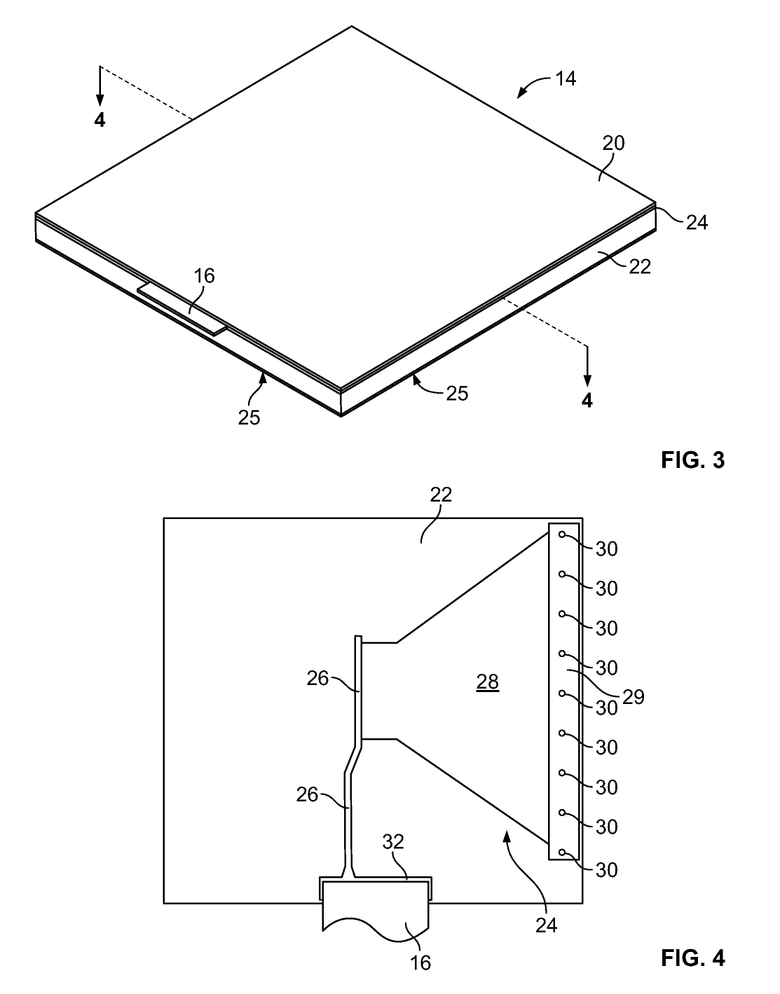

FIG. 3 is a top perspective view of the termination chip 14. The termination chip 14 includes a substrate possessing strong dielectric properties (e.g., an aluminum nitride (AlN) substrate) 22 and a cover 20, with a metallization layer 24 therebetween. The metallized bottom layer 25 is provided on the bottom surface of the termination chip 14 to facilitate soldering of the chip 14 to the mounting flange 12 of FIGS. 1-2. The cover 20 can be an alumina ceramic cover with information (e.g., indicia) printed on it. The cover 20 can be sized and shaped in accordance with the AlN substrate 22, so that the AlN substrate 22, the metallization layer 24, and the cover 20 together form a hexahedron having substantially smooth and flush surfaces. When assembled, the termination chip 14 can have a thickness of 60 mils, and possess a dielectric constant of 8.8. Of course, other thicknesses and dielectric constants are possible. As will be discussed in further detail below, the termination chip 14 is formed through multiple thin-film deposition processes to create an advantageous topology and metallization stackup.

FIG. 4 is a sectional view of the termination chip 14, taken along line 4-4 as seen in FIG. 3. More particularly, FIG. 4 shows a top view of the AlN substrate 22 and the metallization layer 24 of the termination chip 14. The metallization layer 24 includes a metallization pad 32 for receiving the terminal 16. The terminal 16 can be a pure silver terminal that is high temperature soldered to the metallization pad 32. It is noted that no additional processes need to be performed on the pure silver terminal 16. Metallized circuit traces 26 are formed on the AlN substrate 22 for electrically connecting the terminal 16 to a thin-film resistor pad 28. Those in the art will appreciate that the geometry of the metallized circuit traces 26 and the pad 28 shown in FIG. 4 is exemplary, and the geometry of the metallized circuit traces 26 and the pad 28 can be dictated by desired termination characteristics, operating frequencies, etc. The resistor pad 28 can be electrically coupled to a metallization strip 29 disposed at or near an outer edge of the termination chip 14. The resistor pad 28 can be generally trapezoidal in shape as shown in FIG. 4, and is electrically connected between the traces 26 and the metallization strip 29. Of course, other shapes for the resistor pad 28 are possible.

As seen in FIG. 4, the AlN substrate 22 includes metallized vias 30 (shown in phantom lines) positioned beneath the the metallization strip 29. The metallized vias 30 extend through the AlN substrate 22 (e.g., from a top surface of the AlN substrate 22 to a bottom surface of the AlN substrate 22) and electrically connect the metallization strip 29 on the top side of the AlN substrate 22 to the metallized layer 25 formed on the opposite side of the AlN substrate 22, which is then soldered to the copper mounting flange 12. As such, the metallization layer 24 (e.g., the metallization pad 32, the circuit traces 26, the resistor pad 28, and the metallization 29) and the metallization layer 25 formed on the opposite side of the AlN substrate 22 together, through the vias 30, provide electrical continuity from the terminal 16 to the copper mounting flange 12. Thus, because the metallization has continuity through the resistor pad 28 to ground (the ground is the mounting flange 12), the termination chip 14 can serve as the heart from which all the electrical and thermal performance is derived, and the terminator 10 can effectively terminate a 1000 Watt RF power load.

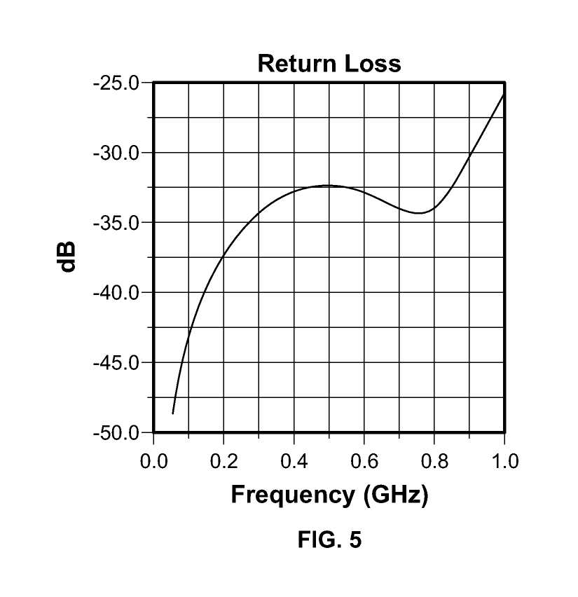

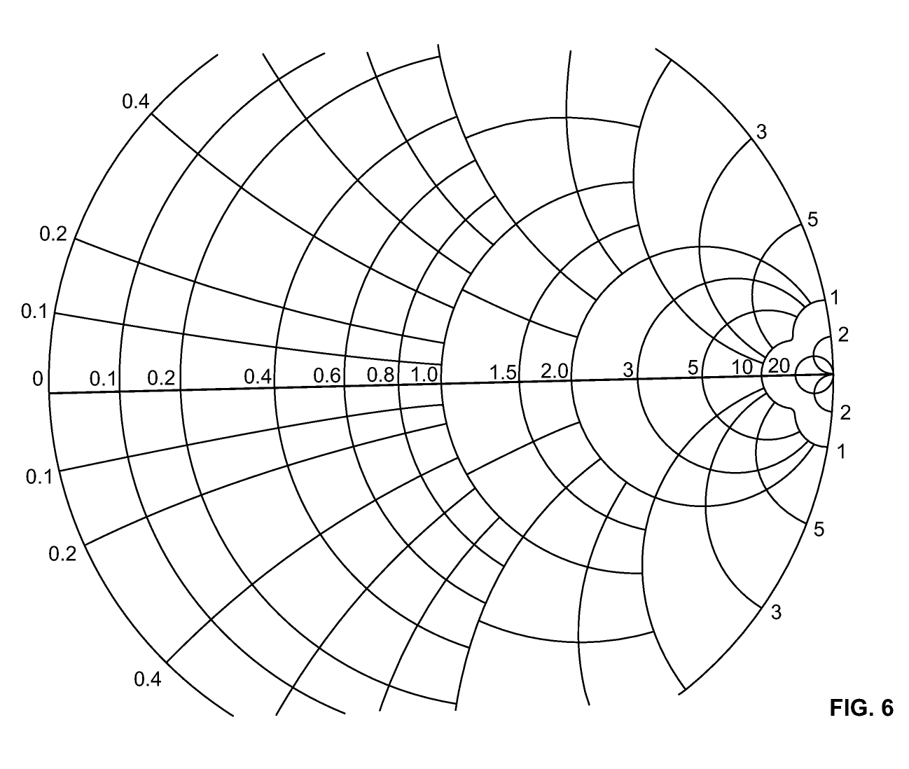

FIG. 5 is a graph showing chip performance. More particularly, FIG. 5 is a graph of return loss as measured as the amount of power lost in the chip as a reflection back to the circuit, and not terminated to ground. As can be seen, signal loss is graphed (in decibels) as a function of operated frequency (in GHz).

FIG. 6 is a graph known to those in the art as a “Smith Chart” for illustrating the impedance of the terminator 10. The Smith Chart is a normalized way of representing the phase of the impedance, by simultaneously showing the Real and Complex portions of the impedance of the terminator 10.

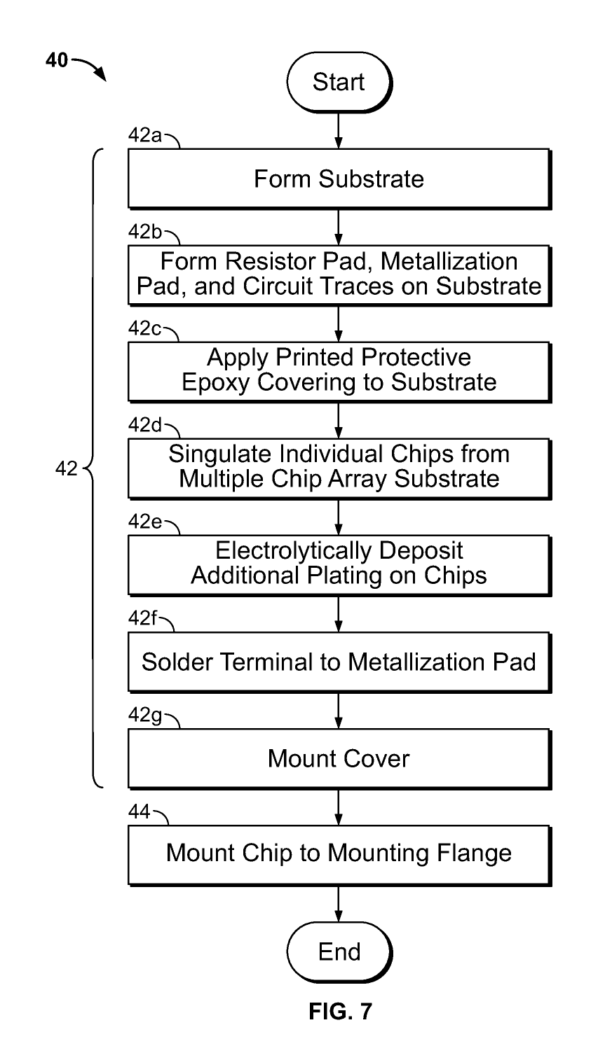

FIG. 7 is a flowchart showing method steps for manufacturing the terminator 10. The terminator 10 is formed through a multiple thin-film deposition process, which creates the topology and the metallization stackup required to create the final chip configuration. The method 40 includes a forming process 42 for forming the termination chip 14, and a mounting step 44 for mounting the termination chip 14 to the mounting flange 12. The forming process 42 includes four sub-steps, i.e., sub-steps 42a-42f. Step 42a includes forming the substrate 22 (e.g., an AlN substrate 22). Step 42b includes forming the metallization pad 32, the metallized circuit traces 26 and the resistor pad 28 on the AlN substrate 22. In step 42b, the metallization 29 can also be formed on the AlN substrate 22. In step 42c, a printed protective epoxy is provided which covers to the substrate 22. In step step 42d, individual termination chips are singulated from a multiple chip array substrate. In step 42e, additional plating is electrolytically deposited on the chips. Also, such plating could involve plating of the mounting flange 12. Step 42f includes high temperature soldering the terminal 16 to the metallization pad 32. In step 42g, the alumina ceramic cover is fastened on top of the AlN substrate 22 the the metallization layer 24. For example, the alumina ceramic cover can be attached with high temperature epoxy (e.g., black thermoset epoxy) to cover the top of the termination chip 14. In step 44, the termination chip 14 is mounted to the mounting flange 12. When mounting the termination chip 14 to the mounting flange 12, the termination chip 14 can be high temperature soldered to the mounting flange 12.

Having thus described the invention in detail, it is to be understood that the foregoing description is not intended to limit the spirit or scope thereof. What is desired to be protected is set forth in the following claims.

What is claimed is:

1. A radio frequency terminator, comprising:
a mounting flange; and
a thin-film termination chip mounted on a surface of the mounting flange, the termination chip including:
a substrate,
a terminal,
a metallization layer including a resistor pad electrically connecting the terminal to the mounting flange, and
a cover;
wherein the mounting flange grounds the termination chip.

2. The radio frequency terminator of claim 1, wherein the substrate comprises one or more metallized vias for electrically connecting the resistor pad to the mounting flange.

3. The radio frequency terminator of claim 2, wherein the metallization layer includes a metallization pad for receiving the terminal, and circuit traces connecting the metallization pad to the resistor pad.

4. The radio frequency terminator of claim 3, wherein the terminal is high temperature soldered to the metallization pad.

5. The radio frequency terminator of claim 1, wherein the thin-film termination chip includes on a bottom surface of the substrate a metallized bottom layer that is soldered to the mounting flange.

6. The radio frequency terminator of claim 1, wherein the thin-film termination chip is high temperature soldered to the mounting flange.

7. The radio frequency power terminator of claim 1, wherein the terminal is a pure silver terminal.

8. The radio frequency terminator of claim 1, wherein the mounting flange is a copper mounting flange.

9. The radio frequency terminator of claim 8, wherein the copper mounting flange is nickel plated.

10. The radio frequency terminator of claim 1, wherein the substrate is an aluminum nitride substrate.

11. The radio frequency terminator of claim 1, wherein the cover is an alumina ceramic cover.

12. The radio frequency terminator of claim 1, wherein the terminator is formed by a multiple thin-film deposition processes.

13. A method for manufacturing a radio frequency terminator, comprising the steps of:
forming a thin-film termination chip; and
mounting the thin-film termination chip to a mounting flange so that the mounting flange grounds the termination chip;
wherein the step of forming the thin-film termination chip comprises:
forming a substrate,
forming a metallization layer on the substrate, the metallization layer including a resistor pad electrically connecting the terminal to the mounting flange,
soldering a terminal to the metallization layer, and
mounting a cover on the substrate and the metallization layer.

14. The method of claim 13, wherein forming the substrate includes forming one or more metallized vias through the substrate for electrically connecting the resistor pad to the mounting flange.

15. The method of claim 14, wherein forming the metallization layer includes forming a metallization pad for receiving the terminal, and forming circuit traces that connect the metallization pad to the resistor pad.

16. The method of claim 13, wherein soldering the terminal to the metallization layer comprises high temperate soldering the terminal to the metallization pad.

17. The method of claim 13, further comprising forming a metallized bottom layer on a bottom surface of the substrate, wherein mounting the thin-film termination chip to the mounting flange comprises soldering the metallized bottom layer to the mounting flange.

18. The method of claim 13, wherein the terminal is a pure silver terminal.

19. The method of claim 13, wherein the mounting flange is a nickel plated copper mounting flange.

20. The method of claim 13, wherein the cover is an alumina ceramic cover.
